(19) United States
(12) Patent Application Publication
(10) Pub. No.: US 2023/0143068 A1
(43) Pub. Date: May 11, 2023

(54) OLED DISPLAY SUBSTRATE AND MANUFACTURING METHOD, COLOR SHIFT ADJUSTMENT METHOD, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Xunfei TONG, Beijing (CN); Dongyu GAO, Beijing (CN); Gen ZHAO, Beijing (CN); Ganghu LIU, Beijing (CN); Huihui LI, Beijing (CN); Han NIE, Beijing (CN)

(21) Appl. No.: 17/913,302

(22) PCT Filed: Nov. 15, 2021
(86) PCT No.: PCT/CN2021/130562

§ 371 Date: Sep. 21, 2022

(30) Foreign Application Priority Data
Feb. 26, 2021 (CN) 202110219199.7

(51) Int. Cl. H10K 59/80; H10K 71/00; H10K 59/35

(52) U.S. Cl. CPC H10K 59/879; H10K 59/35; H10K 59/873; H10K 71/00

(57) ABSTRACT

The present disclosure relates to an OLED display substrate, including: a base substrate; a light emitting structure layer, and a light extraction structure . The light extraction structure includes a plurality of light extraction layers corresponding to the plurality of sub-pixels one-to-one; the orthographic projection of each of light extraction layers on the base substrate covers a corresponding sub-pixel, and the thicknesses of the light extraction layers corresponding to the sub-pixels of the same color are the same. The plurality of light extraction layers at least includes a first light extraction layer corresponding to a first sub-pixel of a first color, and the thickness of the first light extraction layer is different from the thickness of the light extraction layers corresponding to the sub-pixels of other colors, so that the OLED display substrate renders preset colors under preset viewing angles.

### CROSS-REFERENCE TO RELATED APPLICATION

This application claims a priority to the Chinese Patent Application No. 202110219199.7 filed in China on Feb. 26, 2021, the disclosure of which is incorporated herein by reference in its entirety.

### TECHNICAL FIELD

The present disclosure relates to the field of display product manufacturing technology, in particular to an OLED display substrate and a manufacturing method thereof, a color shift adjustment method, and a display apparatus.

### BACKGROUND

OLED has gradually become a new generation of mainstream display technology due to numerous unique advantages such as self-luminous, fast response, low energy consumption, lightweight and ultra-thin, flexible and transparent, healthy and environmental friendly, and wide color gamut. Color shift and efficiency, as two evaluation indexes of OLED products, determine the comprehensive performance of products, and become the main research directions of OLED devices.

Light is emitted from the light emitting side of the OLED display device, and part of the light with a large incident angle is reflected back into the OLED display device and cannot exit. Thus, a light extraction layer may be added outside the light emitting side of the OLED display device to alter the path of light rays, so as to reduce light rays confined within the OLED display device. In the related art, the light extraction layer is a plate-shaped structure, i.e. the thickness of the light extraction layers corresponding to the R/G/B sub-pixels are uniform; however, since the rule of the light characteristics (CIE, eff, L-Decay, etc.) of the R/G/B monochromatic light varying with the thickness of the light extraction layer is inconsistent, By varying the overall thickness of the light extraction layer, at present only a single direction of color shift adjustment can be achieved.

### SUMMARY

In order to solve the above technical problem, an OLED display substrate and a manufacturing method thereof, a color shift adjustment method, and a display apparatus are provided according to embodiments of the present disclosure, solving the problem of a single direction of color shift adjustment.

In order to achieve the above object, the technical solutions adopted by the embodiments of the present disclosure are provided below.

An OLED display substrate, including:
a base substrate;
a light emitting structure layer, which is arranged on a side of the base substrate and includes a plurality of pixel units, wherein each of the pixel units includes a plurality of sub-pixels; and
a light extraction structure, which is arranged on a light emitting side of the light emitting structure layer; wherein the light extraction structure includes a plurality of light extraction layers corresponding to the plurality of sub-pixels one-to-one; the orthographic projection of each of light extraction layers on the base substrate covers a corresponding sub-pixel, and the thicknesses of the light extraction layers corresponding to the sub-pixels of the same color are the same; the plurality of light extraction layers at least includes a first light extraction layer corresponding to a first sub-pixel of a first color, and the thickness of the first light extraction layer is different from the thickness of the light extraction layers corresponding to the sub-pixels of other colors, so that the OLED display substrate renders preset colors under preset viewing angles.

Optionally, the thickness of the light extraction layers is 500-900 Å.

Optionally, the plurality of light extraction layers have a single-layer structure, and the plurality of light extraction layers have different refractive indexes.

Optionally, the plurality of light extraction layers have a single-layer structure, and the plurality of light extraction layers have the same refractive index.

Optionally, the plurality of light extraction layers have a single-layer structure, and the plurality of light extraction layers are independently formed using a plurality of processes.

Optionally, the plurality of light extraction layers have a double-layer structure, and the plurality of light extraction layers includes a first sub-light extraction layer having the same thickness and a second sub-light extraction layer having different thicknesses.

Optionally, the first sub-light extraction layer of the plurality of light extraction layers is formed using a simultaneous process.

Optionally, the refractive index of the first sub-light extraction layer and the refractive index of the second sub-light extraction layer are different.

Optionally, the refractive index of the first sub-light extraction layer and the refractive index of the second sub-light extraction layer are the same.

Optionally, the light extraction layers include a first light extraction layer, a second light extraction layer and a third light extraction layer; the first light extraction layer corresponds to a first sub-pixel having a first color, the second light extraction layer correspond to a second sub-pixel having a second color, the third light extraction layer correspond to a third sub-pixel having a third color; and the first light extraction layer, the second light extraction layer, and the third light extraction layer each have different thicknesses.

Optionally, the thickness of the first light extraction layer is 850-950 Å, the thickness of the second light extraction layer is 750-850 Å, and the thickness of the third light extraction layer is 450-550 Å, so that the OLED display substrate is cyan blue under a pre-set viewing angle.

Optionally, the preset viewing angle is 35-60 degrees.

Optionally, the thickness of the first light extraction layer is 850-950 Å, the thickness of the second light extraction layer is 750-850 Å, and the thickness of the third light extraction layer is 550-650 Å, so that the light efficiency of the OLED display substrate is 61 cd/A, and the color shift of the OLED display substrate under the preset viewing angle is less than 4.8 JNCD.

Optionally, the light emitting structure layer includes an anode, a hole injection layer, a light emitting layer, an electron transport layer, and a cathode which are arranged in sequence, and the light extraction structure is formed at a side of the cathode away from the base substrate.

Optionally, the side of the light extraction structure away from the cathode is formed with an encapsulation layer.

A display apparatus is also provided according to embodiments of the present disclosure, including the above OLED display substrate.

A display apparatus is also provided according to embodiments of the present disclosure, including the above display panel.

A manufacturing method for an OLED display substrate is also provided according to embodiments of the present disclosure, used for manufacturing the above OLED display substrate, wherein the OLED display substrate includes a plurality of pixel units, and each of the pixel units includes a plurality of sub-pixels; and the manufacturing method for an OLED display substrate includes:
providing a base substrate; and
forming a light emitting structure layer on a side of the base substrate;
forming a light extraction structure on a light emitting side of the light emitting structure layer; the light extraction structure includes a plurality of light extraction layers corresponding to the plurality of sub-pixels one-to-one; the orthographic projection of each of light extraction layers on the base substrate covers a corresponding sub-pixel, and the thicknesses of the light extraction layers corresponding to the sub-pixels of the same color are the same; the plurality of light extraction layers at least includes a first light extraction layer corresponding to a first sub-pixel of a first color, and the thickness of the first light extraction layer is different from the thickness of the light extraction layers corresponding to the sub-pixels of other colors.

Optionally, the light extraction layers include a first light extraction layer, a second light extraction layer and a third light extraction layer; the first light extraction layer corresponds to a first sub-pixel having a first color, the second light extraction layer correspond to a second sub-pixel having a second color, the third light extraction layer correspond to a third sub-pixel having a third color;
each of the plurality of light extraction layers include a first sub-light extraction layer, and at least the first light extraction layer include a second sub-light extraction layer arranged on a light extraction side of the first sub-light extraction layer;
the plurality of light extraction layers have a single-layer structure;
the forming the light extraction structure on the light emitting side of the light emitting structure layer, specifically includes:
   forming the first light extraction layer, the second light extraction layer and the third light extraction layer successively by multiple evaporation using a mask plate.

Optionally, the light extraction layers include the first light extraction layer, the second light extraction layer and the third light extraction layer; the first light extraction layer corresponds to the first sub-pixel having the first color, the second light extraction layer correspond to the second sub-pixel having the second color, the third light extraction layer correspond to the third sub-pixel having the third color;
the light extraction layers have a double-layer structure, and the plurality of light extraction layers includes the first sub-light extraction layer having the same thickness and the second sub-light extraction layer having different thicknesses;
the forming the light extraction structure on the light emitting side of the light emitting structure layer, specifically include:
   forming the first sub-light extraction layer of the plurality of light extraction layers; and
   forming the second sub-light extraction layer of each of the light extraction layers on the light emitting side of the first sub-light extraction layer.

Following are advantageous effects of the present disclosure. By setting the light extraction layers corresponding to the sub-pixels of different colors to different thicknesses, the proportion of the light of different colors under a preset viewing angle can be changed, which can not only improve the problem of a large-view color shift towards a yellow region, but also realize multi-directional full-tone color shift adjustment.

### BRIEF DESCRIPTION OF THE DRAWINGS

FIG. 1 is a schematic view of showing the relationship between the thickness of a light extraction layer and the light extraction efficiency;

FIG. 2 is a first schematic view of showing color shift trajectories under a light extraction layer with different thicknesses;

FIG. 3 is a schematic view of showing the variation in luminance attenuation of red light with the thickness of a light extraction layer at a viewing angle of 35 degrees;

FIG. 4 is a schematic view of showing the variation in luminance attenuation of red light with the thickness of a light extraction layer at a viewing angle of 60 degrees;

FIG. 5 is a schematic view of showing the variation in luminance attenuation of blue light with the thickness of a light extraction layer at a viewing angle of 60 degrees;

FIG. 6 is a schematic view of showing the variation in luminance attenuation of blue light with the thickness of a light extraction layer at a viewing angle of 60 degrees;

FIG. 7 is a first schematic view of showing color shift trajectories under a light extraction layer with combinations of different thicknesses;

FIG. 8 is a schematic view of showing the variation of light efficiency of red light with increasing thickness of a light extraction layer;

FIG. 9 is a schematic view of showing the variation of the luminous efficacy of green light with increasing thickness of a light extraction layer;

FIG. 10 is a schematic view of showing the variation of light efficiency of blue light with increasing thickness of a light extraction layer;

FIG. 11 is a second schematic view of showing color shift trajectories under a light extraction layer with combinations of different thicknesses.

### DETAILED DESCRIPTION

The present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

In describing the present disclosure, it should be noted that the terms “central”, “upper”, “lower”, “left”, “right”, “vertical”, “horizontal”, “inner”, “outer”, and the like indicate orientations or positional relationships based on the orientations or positional relationships shown in the figures, merely to facilitate description of the present disclosure and simplify the description, and do not indicate or imply that the referenced devices or elements must have a particular orientation, be constructed and operated in a particular orientation, and thus should not be construed as limiting the present disclosure. Furthermore, the terms “first”, “second”, and “third” are used for descriptive purposes only and are not to be construed as indicating or implying relative importance.

The Light Capping Layer (CPL) is usually located above a metal cathode, and the function thereof is firstly to form a first layer of protection for the cathode; in addition, the characteristics of high refractive index and low absorption coefficient of the material of the light extraction layer also contribute to improving the light extraction efficiency of the device; Further, by adjusting the length of the microcavity by varying the thickness of the light extraction layer, the color shift and efficiency of the device can be adjusted. In the related art, the light extraction layer is a common structure, i.e. a flat plate structure formed by open mask evaporation; the thicknesses of the light extraction layers corresponding to the R/G/B sub-pixels are the same, but since the rules of the respective light characteristics (CIE, Eff., L-Decay, etc.) of the R/G/B monochromatic light varying with the thickness of the light extraction layers are inconsistent, varying the thickness of the light extraction layers can only achieve the adjustment of the color shift in a single direction.

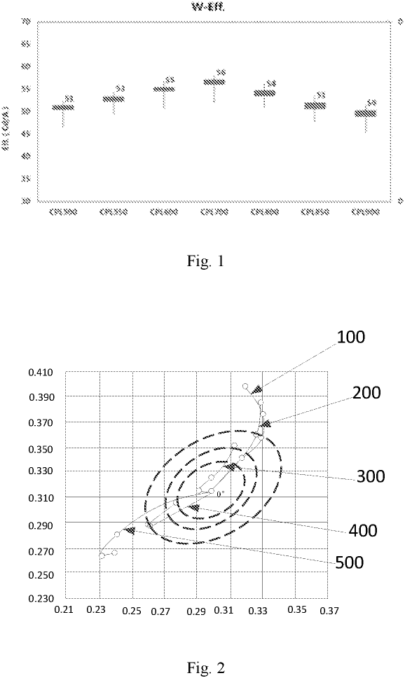

With reference to FIG. 2, each color shift trajectory in FIG. 2 is formed by selecting color shift values at viewing angles of 0 degrees, 35 degrees, 45 degrees and 60 degrees; when viewing angle is 0 degrees, there is no color shift; the greater the viewing angle is, the greater the color shift is; in FIG. 2, the thickness of the light extraction layer corresponding to the first color shift trajectory 100 is 500 Å, the thickness of the light extraction layer corresponding to the second color shift trajectory 200 is 600 Å, the thickness of the light extraction layer corresponding to the third color shift trajectory 300 is 700 Å, and the thickness of the light extraction layer corresponding to the fourth color shift trajectory 400 is 800 Å; the thickness of the light extraction layer corresponding to the fifth color shift trajectory 500 is 900 Å, and the color shift values indicated from the inside to the outside of the dotted circle in FIG. 2 are 3.5 JNCD, 4.8 JNCD and 7 JNCD, respectively. Also, as the thickness of the light extraction layer increases, the overall luminous efficiency increases insignificantly (refer to FIG. 1), and it can be seen that the optical adjustability of the light extraction layer in the form of a flat plate structure is limited.

embodiments of the present disclosure provide an OLED display substrate, including:
a base substrate;
a light emitting structure layer, which is arranged on a side of the base substrate and includes a plurality of pixel units, wherein each of the pixel units includes a plurality of sub-pixels;
a light extraction structure, which is arranged on a light emitting side of the light emitting structure layer. The light extraction structure includes a plurality of light extraction layers corresponding to the plurality of sub-pixels one-to-one; the orthographic projection of each of light extraction layers on the base substrate covers a corresponding sub-pixel, and the thicknesses of the light extraction layers corresponding to the sub-pixels of the same color are the same. The plurality of light extraction layers at least includes a first light extraction layer corresponding to a first sub-pixel of a first color, and the thickness of the first light extraction layer is different from the thickness of the light extraction layers corresponding to the sub-pixels of other colors, so that the OLED display substrate renders preset colors under preset viewing angles.

Exemplarily in this embodiment, the thickness of the light extraction layers is 500-900 Å.

The white light color shift of products is mainly related to the composition ratio of the R/G/B monochromatic light under different viewing angles, while the thickness of the light extraction layers have different influences on the characteristics such as L-decay of the R/G/B monochromatic light under different viewing angles. Taking the thickness gradient within 500 Å∼900 Å of the light extraction layers as an example, the L-Decay variation law of monochromatic lights is explored.

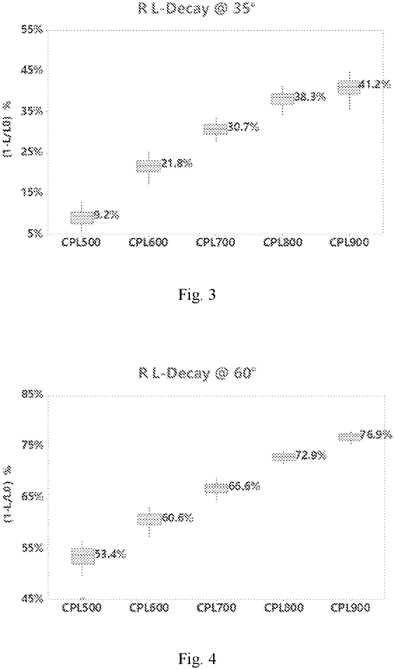

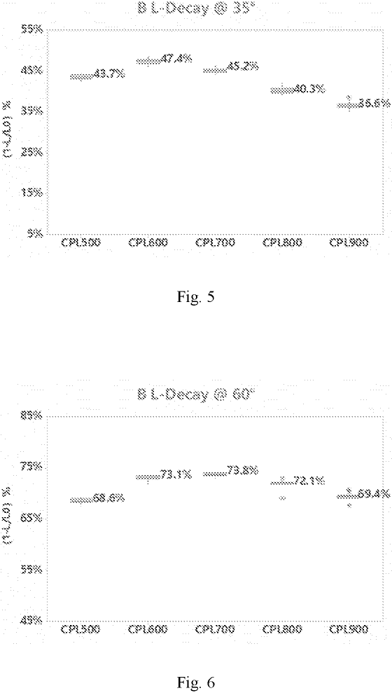

FIG. 3 is a schematic view of showing the variation in luminance attenuation of red light with the thickness of the light extraction layer at a viewing angle of 35 degrees. FIG. 4 is a schematic view of showing the variation in luminance attenuation of the red light with the thickness of the light extraction layer at a viewing angle of 60 degrees. FIG. 5 is a schematic view of showing the variation in luminance attenuation of blue light with the thickness of the light extraction layer at a viewing angle of 60 degrees. FIG. 6 is a schematic view of showing the variation in luminance attenuation of the blue light with the thickness of the light extraction layer at a viewing angle of 60 degrees.

It can be seen from the figures that L-Decay of the red light is most affected by the thickness variation of the light extraction layer. As the thickness of the light extraction layer increases, L-Decay of the red light gradually increases, and the red light component decreases at corresponding viewing angles. However, the green light and the blue light are relatively weakened by the variation of the thickness of the light extraction layer, and present a parabolic law with the increase of the thickness of the light extraction layer, i.e. L-Decay becomes fast first and then slow. The light extraction layers corresponding to the R/G/B sub-pixels are combined at different thicknesses, and there are multiple possibilities for the combination scheme; each scheme at a corresponding viewing angle has a different component ratio of the R/G/B monochromatic light, and multiple color shift trajectories can be obtained by performing white light synthesis.

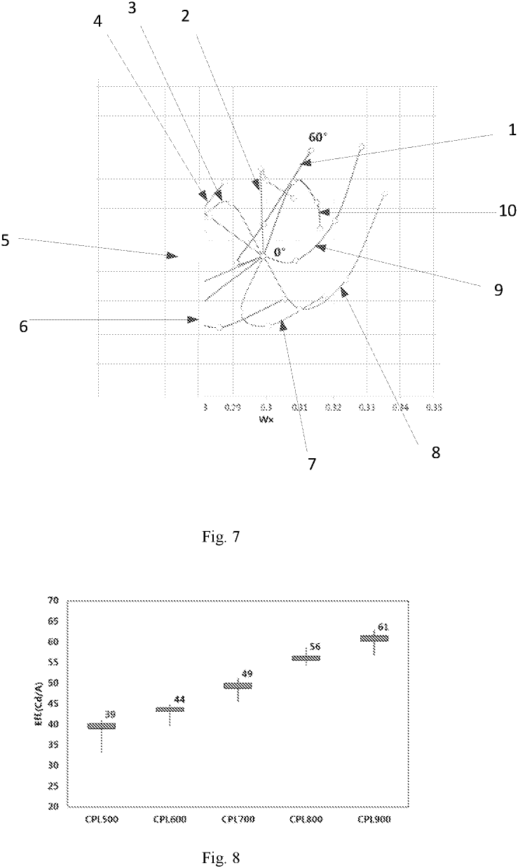

As shown in FIG. 7, FIG. 7 shows part of the color shift trajectories which can be formed by the OLED device of this embodiment, and the thicknesses of different light extraction layers in the light extraction layers has different combinations corresponding to different color shift trajectories. In FIG. 7, a first trajectory is a white light color shift trajectory under the light extraction layer in the form of a flat plate structure (i.e. the light extraction layer with the same thickness), and the remaining trajectories is white light color shift trajectories under the light extraction layers formed by combining light extraction layers with different thicknesses, with reference to the table below.

| Split | Thickness of first light extraction layer | Thickness of second light extraction layer | Thickness of third light extraction layer |
|---|---|---|---|
| First trajectory 1 | 700 | 700 | 700 |
| Second trajectory 2 | 700 | 800 | 500 |
| Third trajectory 3 | 900 | 800 | 500 |
| Fourth trajectory 4 | 900 | 800 | 600 |
| Fifth trajectory 5 | 900 | 800 | 800 |
| Sixth trajectory 6 | 600 | 900 | 900 |
| Seventh trajectory 7 | 500 | 900 | 900 |
| Eighth trajectory 8 | 500 | 700 | 800 |
| Ninth trajectory 9 | 500 | 700 | 700 |
| Tenth trajectory 10 | 500 | 900 | 500 |

It needs to be noted that in the above-mentioned table, the first light extraction layer corresponds to a red sub-pixel, the second light extraction layer corresponds to a green sub-pixel, and the third light extraction layer corresponds to a blue sub-pixel; four nodes represented by four circles on each trajectory line respectively represent that the preset viewing angles are 0 degree, 35 degree, 45 degree and 60 degree; and by adjusting the thicknesses of the light extraction layers corresponding to the R/G/B sub-pixels, color shift trajectory adjustment of different hues is realized, so as to meet different demands of different customers on color shift directions.

It should be noted that the preset viewing angle is the angle between the line of sight of a human eye and the OLED base substrate.

The thickness of the light extraction layers of the OLED display substrate in this embodiment are no longer a flat plate structure, but are divided into light extraction layers corresponding to different color sub-pixels. The thicknesses of the corresponding light extraction layers can be adjusted according to the desired improved color shift direction, and the arrangement of the different thicknesses of the different light extraction layers can vary the component ratio of the R/G/B monochromatic light under a preset viewing angle, so as to improve the problem of a large-view color shift towards a yellow region. In addition, multi-directional full-tone color shift adjustment can be realized through different thickness combinations.

The thickness of each light extraction layer can be adjusted according to different requirements, and the thickness of the first light extraction layer can be different from the thicknesses of other light extraction layers, and the thicknesses of the other light extraction layers can be the same or different.

Exemplarily in this embodiment, the plurality of light extraction layers have a single-layer structure, and the plurality of light extraction layers have different refractive indexes.

The optical effect of the light extraction layers on the R/G/B monochromatic light is related to the thicknesses of the light extraction layers, and is also related to the refractive indexes of the light extraction layers, and varying at least one factor therein can achieve the purpose of improving the light extraction characteristics of corresponding monochromatic light, and in combination with the refractive indexes of the light extraction layers, the thinning of the light extraction layers can be achieved, and further the thinning of the product as a whole can be achieved.

Exemplarily in this embodiment, the plurality of light extraction layers have a single-layer structure, and the plurality of light extraction layers have the same refractive index.

Exemplarily in this embodiment, the plurality of light extraction layers have a single-layer structure, and the plurality of light extraction layers are independently formed using a plurality of processes.

Exemplarily in this embodiment, the plurality of light extraction layers have a double-layer structure, and the plurality of light extraction layers includes a first sub-light extraction layer having the same thickness and a second sub-light extraction layer having different thicknesses.

Exemplarily in this embodiment, the first sub-light extraction layer of the plurality of light extraction layers is formed using a simultaneous process.

Exemplarily in this embodiment, the refractive index of the first sub-light extraction layer and the refractive index of the second sub-light extraction layer are different.

Exemplarily in this embodiment, the refractive index of the first sub-light extraction layer and the refractive index of the second sub-light extraction layer are the same.

In this embodiment, when the light extraction layers are formed, the first sub-light extraction layers of each of the light extraction layers are formed simultaneously; then the second light extraction layer is formed, if the second light extraction layer having the same thickness as the first light extraction layer is present, the second sub-light extraction layers in the first light extraction layer and the second light extraction layer can be formed simultaneously, simplifying the process steps.

Of course, the formation of the light extraction layer is not limited to the above, and the light extraction layers can be formed separately in different processes.

Exemplarily in this embodiment, the light extraction layers include the first light extraction layer, the second light extraction layer and the third light extraction layer. The first light extraction layer corresponds to a first sub-pixel having a first color, the second light extraction layer correspond to a second sub-pixel having a second color, the third light extraction layer correspond to a third sub-pixel having a third color; and the first light extraction layer, the second light extraction layer, and the third light extraction layer each have different thicknesses.

The first color is red, the second color is green, and the third color is blue, but not limited thereto.

Exemplarily in this embodiment, the thickness of the first light extraction layer is a first pre-set value, the thickness of the second light extraction layer is a second pre-set value, and the thickness of the third light extraction layer is a third pre-set value, so that the light emitted by the first sub-pixel, the light emitted by the second sub-pixel and the light emitted by the third sub-pixel are mixed in a pre-set proportion, so as to enable the OLED display substrate to present a pre-set color under a pre-set viewing angle.

In this embodiment, the thickness of the first light extraction layer, the thickness of the second light extraction layer and the thickness of the third light extraction layer are adjusted separately, and can be flexibly set according to a preset display color and the relationship between the thickness of the light extraction layers and the characteristics of each monochromatic light, thereby adjusting the proportion of the corresponding monochromatic light in the white light. For example, in the case of achieving a greenish hue, since the luminance attenuation of the red light gradually increases as the thickness of the light extraction layers increases, the thickness of the first light extraction layer corresponding to the red sub-pixel can be increased accordingly to reduce the proportion of the red light.

Exemplarily in this embodiment, the thickness of the first light extraction layer is 850-950 Å, the thickness of the second light extraction layer is 750-850 Å, and the thickness of the third light extraction layer is 450-550 Å, so that the OLED display substrate is cyan blue under a pre-set viewing angle.

The thickness of the first light extraction layer, the thickness of the second light extraction layer and the thickness of the third light extraction layer are combined at different thickness values so as to achieve a color shift of different colors.

In one implementation of this embodiment, the thickness of the first light extraction layer is 700 Å, the thickness of the second light extraction layer is 800Å, the thickness of the third light extraction layer is 500 Å, and the OLED display substrate is in a green color shift; the thickness of the first light extraction layer is 900 Å, the thickness of the second light extraction layer is 800 Å,the thickness of the third light extraction layer is 600 Å, and the OLED display substrate is in a green color shift; the thickness of the first light extraction layer is 900 Å, the thickness of the second light extraction layer is 800 Å,the thickness of the third light extraction layer is 500 Å, and the OLED display substrate is in a cyan hue shift, the thickness of the first light extraction layer is 900 Å, the thickness of the second light extraction layer is 800 Å,the thickness of the third light extraction layer is 800 Å,and the OLED display substrate is in a cyan hue shift; the thickness of the first light extraction layer is 600 Å, the thickness of the second light extraction layer is 900 Å, the thickness of the third light extraction layer is 900 Å, and the OLED display substrate is in a bluish-purple color shift, the thickness of the first light extraction layer is 500 Å, the thickness of the second light extraction layer is 900 Å, the thickness of the third light extraction layer is 900 Å, and the OLED display substrate is in a basket-purple color shift; the thickness of the first light extraction layer is 500 Å, the thickness of the second light extraction layer is 700 Å, the thickness of the third light extraction layer is 800 Å,and the OLED display substrate is in a pink hue shift; the thickness of the first light extraction layer is 500 Å, the thickness of the second light extraction layer is 700 Å, the thickness of the third light extraction layer is 700 Å, and the OLED display substrate is in a warm white hue shift; the thickness of the first light extraction layer is 500 Å, the thickness of the second light extraction layer is 900 Å, the thickness of the third light extraction layer is 500 Å, and the OLED display substrate is in a warm white hue shift.

As shown in the third trajectory 3 in FIG. 7, the thickness combination of the light extraction layers corresponding to the R/G/B sub-pixel is 900 Å/800 Å/500 Å, the red light L-Decay is faster and the blue light L-Decay is slower, so that the red light component is reduced and the blue light component is increased under a pre-set viewing angle, and therefore the color shift thereof is biased towards a cyan blue region under a large viewing angle, thereby improving the yellowing problem of a product with a large viewing angle (compared with the first trajectory 1 in FIG. 7).

The greater the viewing angle, the easier the color shift occurs, and this embodiment mainly aims at the improvement of the large visual shift, and in particular embodiments, the preset viewing angle is 35-60 degrees, but not limited thereto.

Exemplarily in this embodiment, the thickness of the first light extraction layer is a fourth preset value, the thickness of the second light extraction layer is a fifth preset value, and the thickness of the third light extraction layer is a sixth preset value, so that the light emitted by the first sub-pixel, the light emitted by the second sub-pixel and the light emitted by the third sub-pixel are mixed in a preset proportion, so that the light efficiency of the OLED display substrate is greater than a seventh preset value, and the color shift of the OLED display substrate under the preset viewing angle is less than an eighth preset value.

Exemplarily in this embodiment, the thickness of the first light extraction layer is 850-950 Å, the thickness of the second light extraction layer is 750-850 Å, and the thickness of the third light extraction layer is 550-650 Å, so that the light efficiency of the OLED display substrate is 61 cd/A, and the color shift of the OLED display substrate under the preset viewing angle is less than 4.8 JNCD.

The power consumption of a product is directly related to the efficiency of the OLED device. By varying the length of the microcavity through adjusting the thickness of the light extraction layer to enhance the microcavity effect, the light emitting efficiency can be improved. Taking the thickness gradient of the light extraction layer as 500 Å-900 Å as an example, the variation law of Eff of R/G/B monochromatic light is explored.

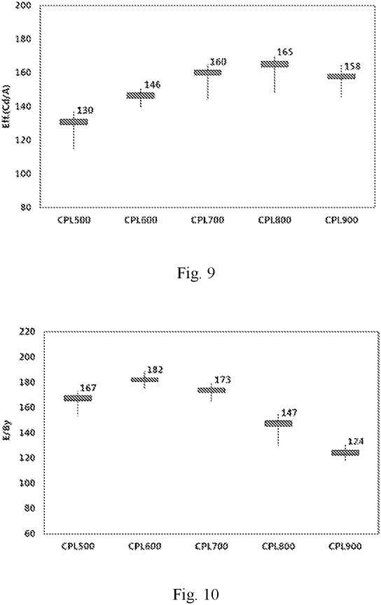

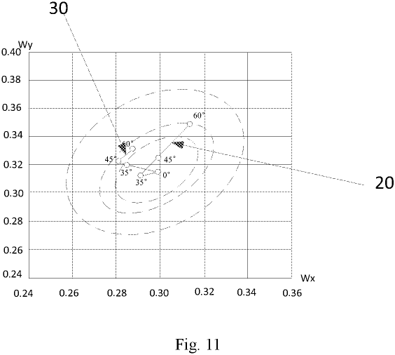

FIG. 8 is a schematic view of showing the variation of light efficiency of the red light with increasing thickness of the light extraction layer, FIG. 9 is a schematic view of showing the variation of the luminous efficacy of the green light with increasing thickness of the light extraction layer, FIG. 10 is a schematic view of showing the variation of light efficiency of the blue light with increasing thickness of the light extraction layer.

It can be seen from the figure that the efficiency of the red light gradually increases with the increasing thickness of the light extraction layer, the efficiency of the green light and the efficiency of the blue light (E/By) first increase and then decrease with the increasing thickness of the light extraction layer, and the efficiency reaches the highest when the thickness of the light extraction layer is 800 Å and 600 Å, respectively. Therefore, the thickness of the light extraction layer corresponding to the R/G/B sub-pixel is respectively set as 900 Å/800 Å/600 Å, that is, the thickness of the first light extraction layer is 900 Å, the thickness of the second light extraction layer is 800 Å, and the thickness of the third light extraction layer is 600 Å, and white light synthesis is performed; the color shift trajectory refers to the eleventh trajectory 30 in FIG. 11, and it can be seen from the figure that under this condition, the light efficiency of the OLED display substrate is 61 cd/A, and the color shift trajectory under the condition of the light extraction layer with the overall thickness of 700 Å refers to the twelfth trajectory 20 in FIG. 11, and the efficiency is improved by 9%, and the power consumption is reduced by 8%; and the corresponding color shift is better, so that the color shift of the OLED display substrate under the preset viewing angle is less than 4.8 JNCD (not being limited thereto). In FIG. 11, the three dotted rings indicate that the color shift values are 3.5 JNCD, 4.8 JNCD and 7.0 JNCD from inside to outside, respectively, and refer to the table below for specific comparisons.

| Item | CPL/ A(R/G/B) | W-eff. | W-JNCD(35°/45°/60°) |
|---|---|---|---|
| Twelfth trajectory | 700 | 56.4 | 1.3/1.7/5.1 |
| Eleventh trajectory | 900/800/600 | 61.2 | 2.9/3.8/3.9 |

It can be seen from the above table that adjusting the thicknesses of the first light extraction layer, the second light extraction layer and the third light extraction layer respectively, and the combination of different thicknesses of the first light extraction layer, the second light extraction layer and the third light extraction layer can improve the light efficiency on the basis of better color shift.

Exemplarily in this embodiment, the light emitting structure layer includes an anode, a hole injection/transport layer, a light emitting layer, an electron transport/injection layer, and a cathode which are arranged in sequence, and the light extraction structure is formed at a side of the cathode away from the base substrate.

Exemplarily in this embodiment, the side of the light extraction structure away from the cathode is formed with an encapsulation layer.

The embodiments of the present disclosure also provides a color shift adjusting method for adjusting the color shift of the above-mentioned OLED display substrate, including:

Adjusting the thicknesses of the different light extraction layers according to the color to be displayed on the OLED display substrate under the preset viewing angle.

In this embodiment, the adjusting the thicknesses of the different light extraction layers according to the color to be displayed on the OLED display substrate under the preset viewing angle, specifically includes:
obtaining a luminance attenuation relationship between the thickness of the light extraction layers and the monochromatic lights of different colors at the preset viewing angle (refer to FIG. 3- FIG. 6);
adjusting the thicknesses of the different light extraction layers according to the luminance attenuation relationship, so that the OLED display substrate renders the preset colors at the preset viewing angle.

With reference to the luminance attenuation law each monochromatic light of the red light, the green light and the blue light with the increasing thickness of the light extraction layer, the thicknesses of the first light extraction layer, the second light extraction layer and the third light extraction layer are respectively adjusted so that the OLED display substrate renders the preset color under the preset viewing angle; and by respectively and independently adjusting the thicknesses of the first light extraction layer, the second light extraction layer and the third light extraction layer, thereby achieving the adjustment of the full color system.

In this embodiment, the adjusting the thicknesses of the different light extraction layers according to the color to be displayed on the OLED display substrate under the preset viewing angle, further includes:
Obtaining a relationship between the thickness of the light extraction layer and the luminous efficacy of the monochromatic lights of different colors at the preset viewing angle (refer to FIG. 8- FIG. 10);
Adjusting the thicknesses of the different light extraction layers, so that the OLED display substrate renders the preset color at the preset viewing angle, and so that the light efficiency of the OLED display substrate is greater than the seventh preset value.

The thickness of the light extraction layer also has an effect on the light efficiency of the OLED display substrate, and the variation law of the light efficiency of different monochromatic lights is different with the variation of the thickness of the light extraction layer; and by combining the brightness attenuation law and the light efficiency variation law of each monochromatic light under different thicknesses of the light extraction layer, the light efficiency can be improved and the color shift can be improved at the same time, so as to achieve the effect of the OLED display substrate assuming the preset color.

Embodiments of the present disclosure also provide a display apparatus including the above-described OLED display substrate.

Embodiments of the present disclosure also provide a manufacturing method for an OLED display substrate, used for manufacturing the above-mentioned OLED display substrate; the OLED display substrate includes a plurality of pixel units, and each of the pixel units includes a plurality of sub-pixels; and the method for manufacturing the OLED display substrate includes the following steps.
Providing a base substrate;
Forming a light emitting structure layer on a side of the base substrate;
Forming a light extraction structure on a light emitting side of the light emitting structure layer. The light extraction structure includes a plurality of light extraction layers corresponding to the plurality of sub-pixels one-to-one; the orthographic projection of each of light extraction layers on the base substrate covers a corresponding sub-pixel, and the thicknesses of the light extraction layers corresponding to the sub-pixels of the same color are the same. The plurality of light extraction layers at least includes a first light extraction layer corresponding to a first sub-pixel of a first color, and the thickness of the first light extraction layer is different from the thickness of the light extraction layers corresponding to the sub-pixels of other colors.

Exemplarily in this embodiment, the light extraction layers include a first light extraction layer, a second light extraction layer and a third light extraction layer. The first light extraction layer corresponds to a first sub-pixel having a first color, the second light extraction layer correspond to a second sub-pixel having a second color, the third light extraction layer correspond to a third sub-pixel having a third color;
each of the plurality of light extraction layers include a first sub-light extraction layer, and at least the first light extraction layer include a second sub-light extraction layer arranged on a light extraction side of the first sub-light extraction layer;
the plurality of light extraction layers have a single-layer structure;
the forming the light extraction structure on the light emitting side of the light emitting structure layer, specifically include:
   forming the first light extraction layer, the second light extraction layer and the third light extraction layer successively by multiple evaporation using a mask plate.

Exemplarily in this embodiment, the light extraction layers include the first light extraction layer, the second light extraction layer and the third light extraction layer. The first light extraction layer corresponds to the first sub-pixel having the first color, the second light extraction layer correspond to the second sub-pixel having the second color, the third light extraction layer correspond to the third sub-pixel having the third color;
the light extraction layers have a double-layer structure, and the plurality of light extraction layers includes the first sub-light extraction layer having the same thickness and the second sub-light extraction layer having different thicknesses;
the forming the light extraction structure on the light emitting side of the light emitting structure layer, specifically include:
forming the first sub-light extraction layer of the plurality of light extraction layers;
forming the second sub-light extraction layer of each of the light extraction layers on the light emitting side of the first sub-light extraction layer.

With the above-mentioned solution, when the thickness of the first light extraction layer and the thickness of the second light extraction layer are the same, and the thickness of the first light extraction layer is less than the thickness of the third light extraction layer, a layer of the first sub-light extraction layer having the same thickness as the thickness of the first light extraction layer can be formed by evaporation first; and then the second sub-light extraction layer in the third light extraction layer is formed on the first sub-light extraction layer. The fabrication of the light extraction layers having the first light extraction layer, the second light extraction layer and the third light extraction layer is formed by a two-step evaporation process, thereby simplifying the process steps and reducing the process difficulty.

While the foregoing is directed to the preferred embodiments of the present disclosure, it will be understood by those skilled in the art that various changes in form and details may be made therein without departing from the spirit and scope of the disclosure.

1. An OLED display substrate, comprising:
a base substrate;
a light emitting structure layer, which is arranged on a side of the base substrate and comprises a plurality of pixel units, wherein each of the pixel units comprises a plurality of sub-pixels; and
a light extraction structure, which is arranged on a light emitting side of the light emitting structure layer; wherein the light extraction structure comprises a plurality of light extraction layers corresponding to the plurality of sub-pixels one-to-one; the orthographic projection of each of light extraction layers on the base substrate covers a corresponding sub-pixel, and the thicknesses of the light extraction layers corresponding to the sub-pixels of the same color are the same; the plurality of light extraction layers at least comprises a first light extraction layer corresponding to a first sub-pixel of a first color, and the thickness of the first light extraction layer is different from the thickness of the light extraction layers corresponding to the sub-pixels of other colors, the OLED display substrate renders preset colors under preset viewing angles.

2. The OLED display substrate according to claim 1, wherein the thickness of the light extraction layers is 500-900 Å.

3. The OLED display substrate according to claim 1, wherein the plurality of light extraction layers have a single-layer structure, and the plurality of light extraction layers have different refractive indexes.

4. The OLED display substrate according to claim 1, wherein the plurality of light extraction layers have a single-layer structure, and the plurality of light extraction layers have the same refractive index.

5. The OLED display substrate according to claim 1, wherein the plurality of light extraction layers have a single-layer structure, and the plurality of light extraction layers are independently formed using a plurality of processes.

6. The OLED display substrate according to claim 1, wherein the plurality of light extraction layers have a double-layer structure, and the plurality of light extraction layers comprises a first sub-light extraction layer having the same thickness and a second sub-light extraction layer having different thicknesses.

7. The OLED display substrate according to claim 6, wherein the first sub-light extraction layer of the plurality of light extraction layers is formed using a simultaneous process.

8. The OLED display substrate according to claim 6, wherein the refractive index of the first sub-light extraction layer and the refractive index of the second sub-light extraction layer are different.

9. The OLED display substrate according to claim 6, wherein the refractive index of the first sub-light extraction layer and the refractive index of the second sub-light extraction layer are the same.

10. The OLED display substrate according to claim 1, wherein the light extraction layers comprise a first light extraction layer, a second light extraction layer and a third light extraction layer; the first light extraction layer corresponds to a first sub-pixel having a first color, the second light extraction layer correspond to a second sub-pixel having a second color, the third light extraction layer correspond to a third sub-pixel having a third color; and the first light extraction layer, the second light extraction layer, and the third light extraction layer each have different thicknesses.

11. The OLED display substrate according to claim 10, wherein the thickness of the first light extraction layer is 850-950 Å, the thickness of the second light extraction layer is 750-850 Å, and the thickness of the third light extraction layer is 450-550 Å, so that the OLED display substrate is cyan blue under a pre-set viewing angle.

12. The OLED display substrate according to claim 11, wherein the preset viewing angle is 35-60 degrees.

13. The OLED display substrate according to claim 10, wherein the thickness of the first light extraction layer is 850-950 Å, the thickness of the second light extraction layer is 750-850 Å, and the thickness of the third light extraction layer is 550-650 Å, so that the light efficiency of the OLED display substrate is 61 cd/A, and the color shift of the OLED display substrate under the preset viewing angle is less than 4.8 JNCD.

14. The OLED display substrate according to claim 1, wherein the light emitting structure layer comprises an anode, a hole injection layer, a light emitting layer, an electron transport layer, and a cathode which are arranged in sequence, and the light extraction structure is formed at a side of the cathode away from the base substrate.

15. The OLED display substrate according to claim 14, wherein the side of the light extraction structure away from the cathode is formed with an encapsulation layer.

16. A display apparatus, comprising the OLED display substrate according to claim 1.

17. A manufacturing method of an OLED display substrate, used for manufacturing the OLED display substrate according to claim 1, wherein the OLED display substrate comprises a plurality of pixel units, and each of the pixel units comprises a plurality of sub-pixels; and the manufacturing method comprises:
providing a base substrate; and
forming a light emitting structure layer on a side of the base substrate;
forming a light extraction structure on a light emitting side of the light emitting structure layer; the light extraction structure comprises a plurality of light extraction layers corresponding to the plurality of sub-pixels one-to-one; the orthographic projection of each of light extraction layers on the base substrate covers a corresponding sub-pixel, and the thicknesses of the light extraction layers corresponding to the sub-pixels of the same color are the same; the plurality of light extraction layers at least comprises a first light extraction layer corresponding to a first sub-pixel of a first color, and the thickness of the first light extraction layer is different from the thickness of the light extraction layers corresponding to the sub-pixels of other colors.

18. The manufacturing method according to claim 17, wherein the light extraction layers comprise a first light extraction layer, a second light extraction layer and a third light extraction layer; the first light extraction layer corresponds to a first sub-pixel having a first color, the second light extraction layer correspond to a second sub-pixel having a second color, the third light extraction layer correspond to a third sub-pixel having a third color;
each of the plurality of light extraction layers comprise a first sub-light extraction layer, and at least the first light extraction layer comprise a second sub-light extraction layer arranged on a light extraction side of the first sub-light extraction layer;
the plurality of light extraction layers have a single-layer structure;
the forming the light extraction structure on the light emitting side of the light emitting structure layer, specifically comprises:
forming the first light extraction layer, the second light extraction layer and the third light extraction layer successively by multiple evaporation using a mask plate.

19. The manufacturing method according to claim 17, wherein the light extraction layers comprise the first light extraction layer, the second light extraction layer and the third light extraction layer; the first light extraction layer corresponds to the first sub-pixel having the first color, the second light extraction layer correspond to the second sub-pixel having the second color, the third light extraction layer correspond to the third sub-pixel having the third color;
the light extraction layers have a double-layer structure, and the plurality of light extraction layers comprises the first sub-light extraction layer having the same thickness and the second sub-light extraction layer having different thicknesses;
the forming the light extraction structure on the light emitting side of the light emitting structure layer, specifically comprises:
forming the first sub-light extraction layer of the plurality of light extraction layers; and
forming the second sub-light extraction layer of each of the light extraction layers on the light emitting side of the first sub-light extraction layer.
